(19) United States
(12) Patent Application Publication
(10) Pub. No.: US 2005/0021254 A1
(43) Pub. Date: Jan. 27, 2005

(54) Method and apparatus for determining the complex impedance of an electrical component

(75) Inventors: Peter Merl, Warminster, PA (US); George Esmet, Jeffersonville, PA (US); Rick Lawrence, Schwenksville, PA (US); Jan-Christoffel Heyneke, New York, NY (US); David Clarke, Kent (GB)

Correspondence Address: SUGHRUE MION, PLLC, 401 Castro Street, Ste 220, Mountain View, CA, 94041-2007, US

(73) Assignee: James G. Biddle Co., Dover, DE (US)

(21) Appl. No.: 10/890,855

(22) Filed: Jul. 13, 2004

(30) Foreign Application Priority Data
Jul. 25, 2003 (GB) 0317513.0

(51) Int. Cl. G01R 27/00

(52) U.S. Cl. 702/65

(57) ABSTRACT

The invention provides a method and apparatus for determining the complex impedance of an electrical component. The method comprises the steps of applying an input signal to the component comprising a plurality of discrete frequencies simultaneously, and determining the complex impedance of the component at each of the frequencies using a discrete demodulation technique on two complex impedance related parameters at each of the discrete frequencies. This method is particularly useful in electrically noisy environments and can be used to determine the impedance and equivalent circuit parameters for a battery. It can also be applied to battery system interconnects to enable battery system currents to be determined.

### FIELD OF THE INVENTION

The present invention relates to a method of analysing the complex impedance spectrum of a circuit or a component in a circuit. In particular the present invention relates to a method of estimating unknown battery degradation using ordinary measurements of the complex impedance spectrum of that battery.

### BACKGROUND TO THE INVENTION

Batteries are increasingly being used in a wide range of applications. Broadly speaking these can be split into three types:

1. primary power for use in portable equipment and mobile devices such as fork lift trucks;

2. start-up power such as for car batteries; and

3. back-up power for uninterruptible power supplies such as for telephone exchanges.

Batteries used for all three of the above types of application are susceptible to failure and degradation. Degradation normally reduces the capacity of the battery but does not perceptibly affect easily measurable parameters such as output voltage. It is particularly important to be able to determine battery capacity for the third type of application mentioned above, i.e. back-up power supplies, as they may be unused for long periods (during which they will degrade) but they must work properly when required. There is therefore a need for test equipment that can identify the degradation of batteries quickly and simply.

It has been shown that the impedance of a battery over time tracks, and so can be used to predict, the degradation of battery capacity Megger's BITE (RTM) series of testers for example, use an AC signal to measure the scalar impedance of a battery.

There are a number of different mathematical models that exist for battery capacity, different models being appropriate for different types of battery and different levels of accuracy. In particular, there are a number of equivalent circuit battery models which have been proposed. One example of such an equivalent circuit is the well known circuit proposed by Randles, which consists of two resistors and a parallel capacitor. This is shown in FIG. 1. These components will degrade during the life of the battery. The capacitance component will degrade at an earlier stage than the resistive components. Measurement of all three equivalent components can therefore be used to give a prediction of the age and health of the battery.

With the circuit model as proposed by Randles however, it is necessary, in order to determine the values of the equivalent components, to measure the complex impedance spectrum of the battery and to match it to the complex impedance spectrum of the equivalent circuit. This holds equally true for other equivalent circuits which may include a greater number of components. It should be noted that the three component Randles circuit usually forms a part of the more complex models along with additional components.

Hampson et al., The impedance of electrical storage cells,” Journal of Applied Electrochemistry, volume 10 1980, pp 3-11, discloses a more elaborate approach involving additional components dependant on the cell chemistry. Other works propose either theoretical or empirical methods for fitting a curve or function representing the state of charge of a battery versus measured complex impedance parameters. Yoon for example proposes such a method in U.S. Pat. No. 6,160,382.

Back up power supply batteries are of necessity, large and have low resistance and high capacitance. This combination of values is such that they do not contribute significantly to the scalar impedance or phase shift at frequencies above 0.1 Hz. Furthermore, back up power supply batteries are often installed in locations of high electrical noise, such as electricity sub-stations. They may also be permanently connected to a charging system capable of delivering hundreds of amps. This combination of factors makes the accurate determination of battery impedance spectra extremely difficult.

Various methods have been proposed for such a measurement. GB2175700A discloses a method based on the application of a voltage signal composed of a pseudo random binary sequence or PRBS followed by sampling of the voltage and current waveforms. After fast Fourier transforming both of the sampled waveforms an impedance spectrum is arrived at by division. GB 2175700A further proposes determining the frequency at which the maximum reactance occurs for a sealed lead acid battery and a calibration store for determining the battery residual capacity from that frequency. It can be shown that this frequency value and the value of the corresponding most reactive impedance allow both resistive and capacitive components of the Randles equivalent circuit to be determined.

However, there are problems with the method disclosed in GB 2175700A. In practice, the time constant of a typical battery is long, making frequency which gives rise to the maximum reactance value low and the resulting test length unacceptable. Furthermore, it is difficult to estimate the maximum value of reactance without taking measurements over the range of frequencies around that maximum value. The Fourier transform of the entire frequency range takes a long time and the process does not allow any information to be determined until the whole process has completed.

In contrast to the aperiodic multi-frequency method characterized by the pseudo random binary sequence of GB 2175700A, U.S. Pat. No. 6,172,483 proposes to measure the complex impedance at a single frequency using a periodic waveform stimulus comprising one or more frequencies. U.S. Pat. No. 5,717,336 proposes an assessment of the charge based on the slope of impedance with frequency and suggests the use of a synchronous detector, based on switching techniques, for each of the frequencies used.

Further problems, not addressed by the above, arise from the presence of large AC and DC voltage and current signals in the battery system during the test. Since it is desirable that the battery system should remain connected both to any charger and to any loads during the test load currents and charger currents will continue to flow resulting in voltage signals at the battery in response to these currents. In the case of a portable test instrument for testing large batteries, the magnitudes of these signals will exceed those of any signals the test instrument could impose.

Faced with such potential interference the test instrument is best constructed so as to apply the largest signals possible, likely values being of the order of 1 to 10 amps in the case of large batteries. While small signals would normally be applied for the determination of such an equivalent circuit, this approach must be abandoned in the presence of much larger interfering signals. Under such circumstances the non-linear voltage versus current characteristics of both the load and the charger can be expected to influence the measurement. This will occur whether or not the battery itself continues to act linearly in accordance with simple circuit models, such as that proposed by Randles.

One effect of such non-linearities is to create harmonics of the signals applied from each of the sources. Consequently harmonics of the individual frequency components of the charger currents, load currents and the current applied by the test instrument are encountered in the measured signals. Additionally intermodulation effects may occur between each of these frequency components. Inaccuracies will result if a signal resulting from a harmonic or from intermodulation coincides with a measurement frequency. As a consequence a method which relies on simultaneous measurements at large numbers of frequencies could produce confusing results with poor repeatability.

This problem has been recognized by others. U.S. Pat. No. 6,160,382, for example, proposes a complex non linear circuit model for the battery itself and the determination of the complex impedance spectrum using either swept frequency, Fourier transform or Laplace methods pointing out that additional undesired frequencies can be generated as a result of such non-linearities and proposing a check on the magnitude of such additional signals to ensure correct results. Essentially, the teaching of U.S. Pat. No. 6,160,382 is to use small amplitude signals for the measurement so as to minimize the magnitude of the unwanted additional signals.

An alternative approach is proposed by WO93/2266, in which the currents resulting from the load and charger are used as the test stimulus. While this would typically provide larger signals than a portable instrument could apply, it prevents control of the frequencies at which the impedance measurements are made and so eliminates the possibility of selecting frequencies so as to minimize the effects of intermodulation and harmonics.

Existing portable battery testers, such as Megger's BITE series, operate at a single frequency of the order of 55 Hz. At such frequencies a single impedance measurement can be made in the order of a second or less. However, in order to obtain useful information about a large battery it is necessary to make measurements at frequencies a hundred times lower. At such frequencies the time required for even a single measurement might exceed the patience of the operator. Therefore, if the constraints caused by intermodulation and harmonics were to result in the need for sequential measurements at individual frequencies the test would become impractical.

In summary, a method based on GB 2,175,700A would be workable under linear (small signal) conditions given sufficient time to perform the test. This would be unacceptably long however to encompass frequencies both above, and especially below, the frequency at which the battery appears the most reactive.

Owing to their relatively high frequency of operation, existing battery testers are able to provide a continuous reading of impedance as the test progresses. This feature is key to avoiding operator frustration which might result in the test being abandoned and is highly desirable in future testers.

It is therefore an object of the present invention to provide a method of determining battery capacity that can be completed in a shorter time and which allows a user to see up-dated values of the battery capacity as the method proceeds. It should be appreciated, however, that the present invention can be applied to the testing of other electrical components as well as batteries.

### SUMMARY OF THE INVENTION

According to the present invention, there is provided a method of determining the complex impedance spectrum of a circuit component comprising the steps of:

applying an input signal to the component comprising a fixed duration of a plurality of discrete frequencies simultaneously; and

determining the complex impedance of the component at each of the frequencies using a discrete demodulation technique on two complex impedance related parameters at each of the discrete frequencies;

wherein none of the discrete frequencies is an integer multiple of any other of the discrete frequencies, and

wherein none of the discrete frequencies is a sum of any other two of the discrete frequencies.

Preferably, the demodulation technique is a single frequency homodyne demodulation which is performed at each of the discrete frequencies. Alternatively, it may be a multiple frequency homodyne demodulation technique.

The method of the present invention is particularly useful in electrically noisy environments or when testing must be performed on a component in an operating circuit carrying large electrical signals, such as a back up battery for an uninterruptible power supply. When the circuit component is operating in an electrical system, it is preferred that each of the discrete frequencies are different to the frequency of currents in the system.

The duration for which the signal is applied is preferably such that it contains an integer number of cycles of each of the discrete frequencies. Preferably, the minimum duration that satisfies this condition is chosen in order to minimise the amount of processing required. The input signal as a whole is then aperiodic as it does not repeat itself.

The duration of the input signal is chosen to be an integer number of cycles of each of the discrete frequencies in order to reduce the frequency content of the demodulated input signal and to ensure that artefacts are not produced as a result of the demodulation technique.

Preferably, the input signal is a current waveform. Alternatively, the input signal may be a voltage waveform.

Preferably, the plurality of discrete frequencies are applied as a sequence of samples, the sequence containing an integer multiple of cycles of each of the discrete frequencies. Preferably, processing of the discrete frequencies is performed on a sequence of samples, the sequence containing an integer multiple of cycles of each of the discrete frequencies

Preferably, the duration of the input signal is adjusted so as to comprise a whole number of cycles of an interfering signal. This also done to avoid the generation of artefacts in the demodulated signals. In the presence of non-linearities, either in the battery itself or in the attached load and charger, it is essential to carefully control the spectrum of the applied signal and the frequencies used for the impedance measurement, taking into account also the frequencies of the major components of the signals produced by the load and the charger themselves.

Preferably, the number of samples in the sequence is the lowest common multiple of all of the frequencies Fᵢ in Hz multiplied by the lowest factor that R such that all Fᵢ*R are integers. Preferably, the sequence length allows the demodulation to be performed over a whole number of cycles simultaneously for each of the discrete frequencies.

Preferably, a noise signal is also applied across the terminals of the battery simultaneously with the discrete frequencies. The noise signal can ameliorate problems arising from quantisation which occurs as a result of the input signal being applied as a sequence of samples.

The value of the complex impedance is obtained from two streams of impedance related parameters. Preferably these parameters are voltage and current.

Preferably, the values of the parameters are updated, synchronously with each other for each of the frequencies, at various points in time taking into account all the samples taken up to that point.

Preferably, the method further includes the step of deriving the values of equivalent circuit parameters from the complex impedance of the component at each of the frequencies. Preferably, an estimate of at least one of the equivalent circuit parameters is updated and displayed at various points in time.

Preferably, the circuit component is a battery. Preferably the equivalent circuit parameters are based on the Randles equivalent circuit for a battery and at least four discrete frequencies are used.

Preferably, the derivation of the values of the equivalent circuit parameters includes the step of fitting a curve to a plot of the complex impedance at each of the discrete frequencies or the equivalent thereof, wherein each of the values of the equivalent circuit parameters can be mathematically derived from the curve.

According to a second aspect of the present invention, a circuit component impedance tester comprises:

signal generation means for applying an input signal, comprising a fixed duration of a plurality of discrete frequencies simultaneously, across the component;

sensing means for detecting two impedance related parameters from the component; and,

processing means for demodulating the measured impedance related parameters at each of the discrete frequencies;

wherein none of the discrete frequencies is an integer multiple of any other of the discrete frequencies, and

wherein none of the discrete frequencies is a sum of any other two of the discrete frequencies.

Preferably, the tester further comprises a user interface for displaying the equivalent circuit parameters.

Preferably, the processing means uses a single frequency homodyne demodulation technique performed at each of the discrete frequencies. Preferably, the signal generation means generates a current waveform.

Preferably, the signal generation means generates the input signal as a sequence of samples. Preferably, the processing means analyses the plurality of discrete frequencies as a sequence of samples. Preferably, the sequence contains an integer multiple of cycles of each of the discrete frequencies. Preferably, the sequence contains an integer number of cycles of an interfering signal.

Preferably, the number of samples in the sequence is the lowest common multiple of all of the frequencies Fᵢ in Hz multiplied by the lowest factor that R such that all Fᵢ*R are integers. Preferably, the sequence length allows the demodulation to be performed over a whole number of cycles simultaneously for each of the discrete frequencies. Preferably, the signal generation means includes a digital to analogue converter (DAC) for converting the sequence of samples into a waveform. Preferably, the sensing means detects current and voltage signals.

Preferably, the processing means includes a plurality of circular accumulators. Preferably, the processing means includes a circular accumulator corresponding to each impedance related parameter at each discrete frequency, the length of each accumulator corresponding to the number of samples per cycle at that frequency. The circular accumulators form part of a Homodyne demodulation system designed to operate so as to detect only the desired frequency in order to reduce the number of calculations required to be performed during demodulation.

Preferably, the processing means further comprises means for deriving from the demodulated impedance related parameters, equivalent circuit parameters for the component.

The tester is particularly suitable for determining equivalent circuit parameters for batteries. In this case it is preferred that processing means uses the Randles equivalent circuit model and that at least four discrete frequencies are used.

Preferably, the processing means updates the values of the equivalent circuit parameters, synchronously with each other for each of the frequencies, at various points in time taking into account all the samples taken up to that point. Preferably, the processing means updates and displays an estimate of at least one of the equivalent circuit parameters at various points in time throughout the test sequence.

Preferably, the tester further includes a pair of probes which are applied to the component to be tested, each probe comprising a pair of contacts.

According to a third aspect of the present invention, a method of determining electrical system currents comprises the steps of:

determining the impedance of an electrical interconnect in accordance with the method of the first aspect of the invention;

measuring the voltage drop across the interconnect as a result of the system currents; and,

determining the system currents from the impedance and voltage using Ohm's law.

Preferably, the frequencies used to determine the impedance of the interconnect are chosen so as to avoid interference with those comprising the system currents. Preferably, the electrical system is a battery system.

Preferably, a tester according to the second aspect of the invention further comprises:

means for measuring a voltage drop across an interconnect; and

means for deriving electrical system currents from the impedance related parameters and the voltage drop using Ohm's law.

Preferably, the discrete frequencies used to determine the impedance of the interconnect are chosen to avoid interference with those comprising the system currents.

### BRIEF DESCRIPTION OF THE DRAWINGS

Examples of the present invention will now be described with reference to the accompanying drawings, in which:

FIG. 1 is a circuit diagram of the Randles equivalent circuit for a battery;

FIG. 2 is a plot of the complex impedance of the circuit shown in FIG. 1 at a range of frequencies;

FIG. 3 is a plot of the square of the reactance versus the resistance for a range of frequencies for the circuit shown in FIG. 1;

FIG. 4 is a schematic illustration of a battery tester according to the present invention;

FIG. 5 is a schematic illustration of a set of accumulators in a tester according to the present invention; and,

FIG. 6 illustrates the positions of the probes when measuring interconnect resistance.

### DETAILED DESCRIPTION

The present invention will be described with reference to the Randles equivalent model for the resistive and reactive components of a battery. However, it should be clear that the method and apparatus of the present invention can be applied to any model of a battery or to other electrical components.

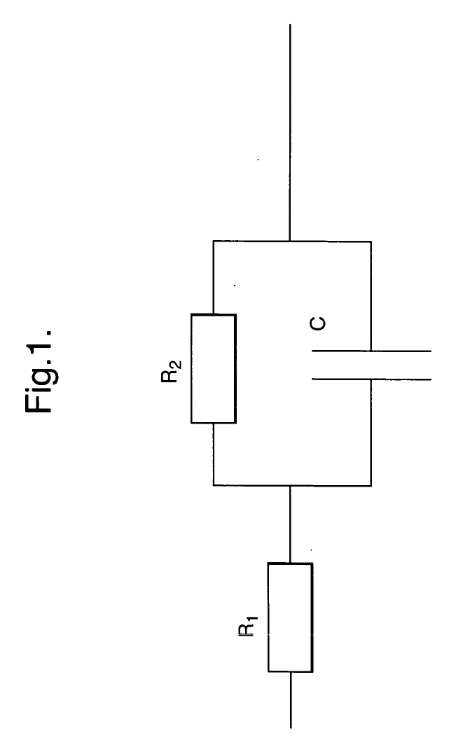

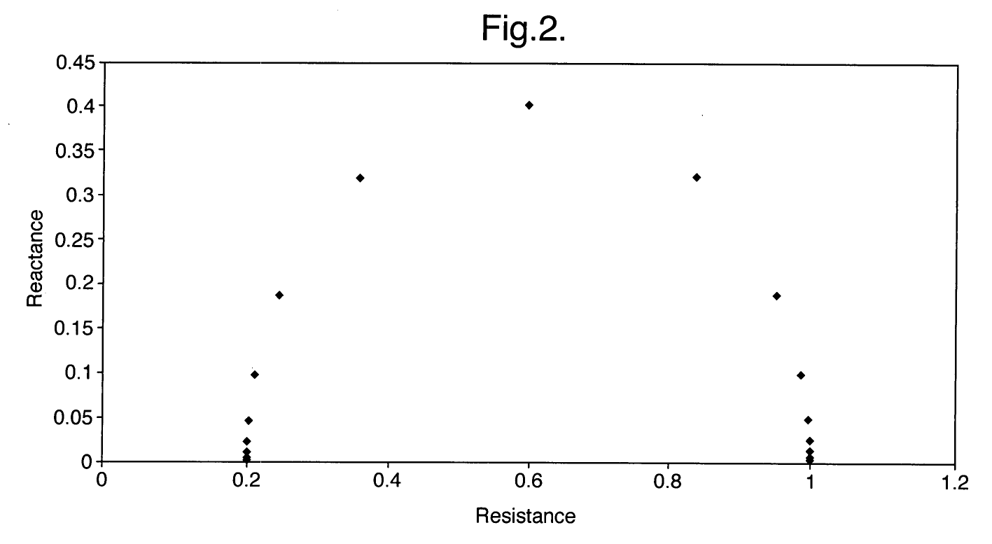

FIG. 1 shows the Randles equivalent circuit for a battery, comprising a first resistor R1 connected in series with a second resistor R2 and a capacitor C connected in parallel. The complex impedance of this circuit is plotted at a number of frequencies in FIG. 2. Each point plotted in FIG. 2 represents a frequency one octave lower than the next when moving from left to right. The plotted points all lie on a semicircle from which it is possible to determine the point of maximum reactance and hence the values of R1, R2 and C. The point of maximum reactance occurs at a resistance of (R1+R2)/2 and the maximum reactance equals the radius of the circle i.e. R2/2. This allows R1 and R2 to be calculated directly. Furthermore C can be calculated from the frequency at which the maximum reactance occurs.

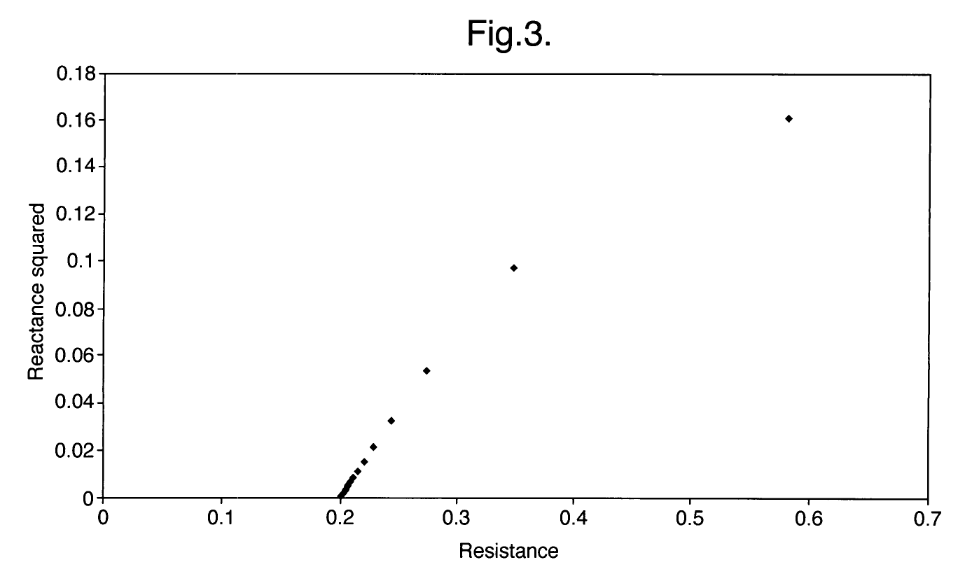

It will often be the case however that, due to the magnitudes of the equivalent circuit components, none of the frequencies used by the tester will generate a significant phase shift, i.e. the points measured will all correspond to either the left or right hand extreme of the semicircle shown in FIG. 2 and there will be minimal reactance. However, it can be shown that for such a circuit the square of the reactive component varies linearly with the resistive component for both high and low frequencies at the ends of the semicircle. The linearity holds well for angles around the semicircle between 0 and 30 degrees and 150 to 180 degrees. As can be seen from FIG. 2, this corresponds to many octaves. Using this linear relationship it is possible to determine R1 and R2. R2 is determinable from the gradient of a plot of reactance squared versus resistance and R1 from the intercept of the plot with the resistive axis. This is shown in FIG. 3. The value of C can then be determined from a single frequency measurement of impedance, by substituting in the values of R1 and R2.

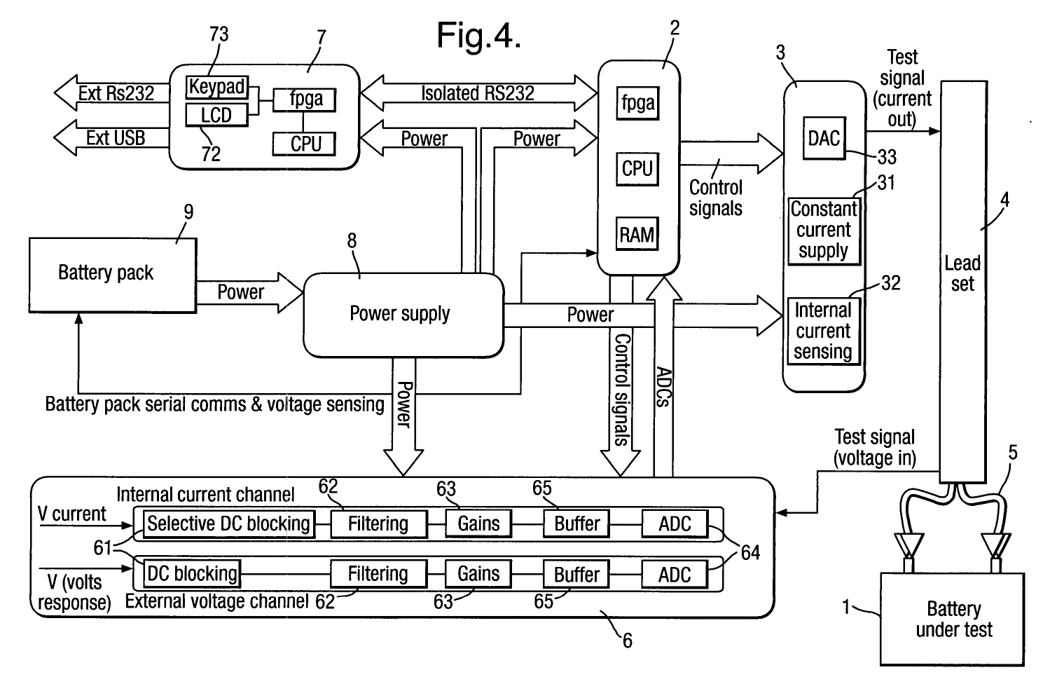

FIG. 4 shows schematically a test apparatus in accordance with the present invention. The apparatus is shown connected to a battery under test 1. The apparatus comprises an internal controller 2 connected to a signal generation circuit 3. The signal generation circuit is connected to the battery under test via a lead set 4 and a pair of probes 5 which connect to the battery under test. The probes are also connected to a sensing circuit 6 that detects both current and voltage waveforms and performs some signal processing. The sensing circuit 6 is connected to the internal controller 2, which is in turn connected to a user interface 7. Each of the two probes 5 includes a pair of contacts such that together with the lead set 4 they form a four terminal impedance measurement. Four terminal measurement is essential for the accurate determination of low impedances in order to eliminate the voltage drop caused by the current flowing in the leads from the tester to the battery under test.

The lead set 4 is designed to ensure that inductive and capacitive coupling between the current path and the voltage input is minimised. This precaution is essential given the low impedances and large AC current applied.

The internal controller 2 controls the timing of input and output samples via the analogue to digital converters and digital to analogue converters in the sensing 6 and generation 3 circuits respectively and also initiates the current output from the latter. The internal controller 2 is electrically isolated from the User Interface 7 for safety and in order to preserve the integrity of communications from the latter to external devices. The controller 2 comprises a small microprocessor and timing control circuitry incorporated in a programmable gate array. It is designed so as to be able to perform a complete test autonomously so as to ensure that the timing of input and output waveforms is not disrupted by concurrent calculation, communications or user input.

A power supply 8 provides regulated power to all the circuit elements and in particular isolated power to the user interface 7. The power supply is provided by a battery pack 9.

In order to produce the plots of FIGS. 2 and 3 it is necessary to apply a voltage or current signal across the terminals of the battery 1 at a series of different frequencies. As stated above, it has been suggested to use a pseudo-random noise signal to perform the test. This encompasses a broad spectrum of frequencies and takes a long time to process. Furthermore, battery testing often has to take place in electrically noisy environments, for example an electricity substation. This fact, compounded with problems associated with non-linear effects makes it difficult to extract an accurate measure of complex impedance.

In this example of the present invention, a fixed duration of a plurality of discrete frequencies are applied simultaneously across the battery 1. The discrete frequencies are generated by the signal generation circuit 3. The signal generation circuit 3 is designed so as to generate an accurate current waveform under the command of the internal controller 2. The current waveform adds to any current already flowing from the charger or the load to which the battery is connected. A voltage waveform could be used as an alternative. The signal generation system comprises a variable constant current supply 31, internal current sensing 32 for the purposes of feedback and also to detect the proper connection of the probes, and a digital to analogue converter (DAC) 33. The current signal is created from a stored or calculated waveform that is applied as a sequence of samples from the DAC. Analogue waveforms are therefore applied across the battery 1 and the resulting current and voltage detected by the sensing circuit 6. Timing and control signals as well as sample data are supplied to the signal generation circuit 3 from the internal controller 2.

The Nyquist plot for the Randles equivalent circuit is a semicircle. It is possible to fit a circle to any three points in a plane and so it is necessary to use at least four different frequencies to get a meaningful result. For example, the frequencies 55 Hz, 13 Hz, 3 Hz and 2 Hz could be used. The actual choice of frequencies depends on many factors as described below, the example set of frequencies above complies with the requirements of the invention but is used for illustrative purposes only.

The voltage and current outputs at those frequencies are extracted and the complex impedance at those frequencies subsequently derived to provide a plot as shown in FIG. 2 and/or FIG. 3. The extraction of the voltage and current signals is started by the sensing circuit 6. The sensing circuit filters and amplifies the voltage and current signals coming from the lead set and from the signal generation circuit respectively. In normal operation both the voltage and the current channel are organised so as to block the DC component using DC filters 61, filter out high frequency signals using further filters 62, amplify the result using gain circuits 63 and provide it to one of two analogue to digital converters (ADCs) 64.

The sensing circuit also includes circular arrangements of accumulators 65 (circular accumulators) which form part of a homodyne demodulation system used to detect the signal and to discard the remainder of the spectrum. Their use reduces the number of calculations required and allows a discrete demodulation technique to be employed. If P discrete frequencies are used, then the sensing circuit includes P circular accumulators for the current data signals and P accumulators for the voltage data signals. The number of accumulators in each circular arrangement corresponds to the number of samples per cycle for each of the P frequencies in use.

After any complete number of cycles of a given signal the values in the corresponding circular accumulators are multiplied by coefficients representing sine and cosine components of the desired frequency and the results of the multiplications added to form a pair of sine and cosine values representative of the amplitude and phase of the detected signal times the number of cycles elapsed.

It is an aim of the present invention to allow a separation of the measurement and calculation portions of the resulting test instrument. The use of circular accumulators in the measurement section provides numerous advantages.
The volume of data to be transferred during the measurement portion of a test can be reduced to zero without the need for large amounts of data storage in the small processor used for the measurement section.
The above remains true irrespective of the duration of the test.
The main processor 71, located in the user interface 7 can nevertheless request a snapshot of the values in any of the accumulators at any time and so provide a regular update for the user in the case of a long test.
By means of reducing the communications traffic and processing required during the test the electrical noise within the tester is minimized thus improving the accuracy of the small signal measurements required.

As stated above, the accumulators in the sensing circuit 6 are each of a length corresponding to the number of samples per cycle of the frequency for which that accumulator is intended. To ensure an integer number of samples per cycle for selected frequencies F_{P} where F_{P}>1, N could be chosen such that N=F₁.F₂.F₃ . . . F_{P}. A more complete rule is that N is the lowest common multiple (LCM) of G_{P} where G_{P} are derived as follows: G_{P}=R.F_{P} where R is a multiplier so that all G_{P} are integers >1. In the case of frequencies 55, 13, 3, 2 the lowest possible G_{P} are also 55, 13, 3, 2 and the LCM N=4290. Therefore there must be 4290 samples (or a multiple thereof) in a sequence using these frequencies.

Any non-linearity in the system will generate both harmonics of the frequencies used and intermodulation between them. Non-linearities will occur as a result of the battery and non-linear components in the system such as diodes in charging circuits. Therefore, in order to extract the most accurate results, the chosen frequencies should not be multiples of each other i.e. for any two frequencies a, b, n.a≠b, where n is an integer. Furthermore, to avoid problems with intermodulation for any three chosen frequencies a, b, c, the condition a+b≠c should be satisfied.

In order to detect the discrete frequencies in a quick and efficient manner a homodyne demodulation is performed on the output voltage and current signals. In this embodiment, single frequency homodyne demodulation is performed at each of the discrete frequencies. Homodyne demodulation implements a process equivalent to extracting the real and imaginary components of a single frequency of a Fourier transform of the signal. Extraction of the real and imaginary parts of both the current and the voltage at each of the frequencies allows the complex impedance at that frequency to be calculated. This corresponds to a single plot on the graph of FIG. 2 or FIG. 3. Calculation at each of the frequencies allows a series of points to be plotted and subsequently the values of R1, R2 and C to be calculated.

Homodyne demodulation can be implemented using either digital or analogue techniques. In a digital environment it can be thought of as implementing a single frequency of a discrete Fourier transform. Suitable analogue methods would be based on the use of local oscillators and mixers and would be familiar to one skilled in the art of high performance radio receivers where the technique is referred to as zero IF. As a discrete Fourier transform it can be written as:

$${G}_{w} = {\sum }_{i = 1}^{N} {S}_{i} \cdot {ⅇ}^{- j w T s i}$$

where Ts is the sampling interval and Sᵢ are the values of the samples. The process can be thought of as separating the signal into sine and cosine components at the defined frequency or frequencies.

In a preferred embodiment, the homodyne demodulation is performed by the user interface 7, owing to the amount of processing required and the need for the measurement electronics to be low power and low noise. The user interface 7 comprises an LCD display 72, keypad 73, communications ports for external devices and isolated communications to the internal controller 2. The user interface 7 handles the storage and calculation of results as well as the sequence of multi cell tests. Derivation of lumped impedance equivalents to the battery under test is carried out by software in the user interface 7 once the test waveform has been applied and the response measured.

It is also desirable that the duration of the sequence of samples be an integer multiple of the period of the predominant interfering signal, e.g. the mains at 50 Hz or 60 Hz. The sample period may therefore be phase locked to the interfering signal to improve rejection of the interfering signal.

It is desirable to allow a user of the battery tester to see at least one of the equivalent circuit parameters displayed and updated throughout the test as it settles down to a steady value. In this way the tester mimics existing instruments such as the BITE2 (RTM) tester. The processing described above gives correct values for the sine and cosine components of voltage and current for each frequency provided an integer number of cycles have been processed. It is therefore possible, for example to update a value for R1 each time the circular accumulator for the highest frequency has been added to an integer number of times. In the case of frequencies 55, 13, 3 and 2 Hz and the 2 second 4290 sample sequence, this would be every 39 samples corresponding to every cycle of the 55 Hz.

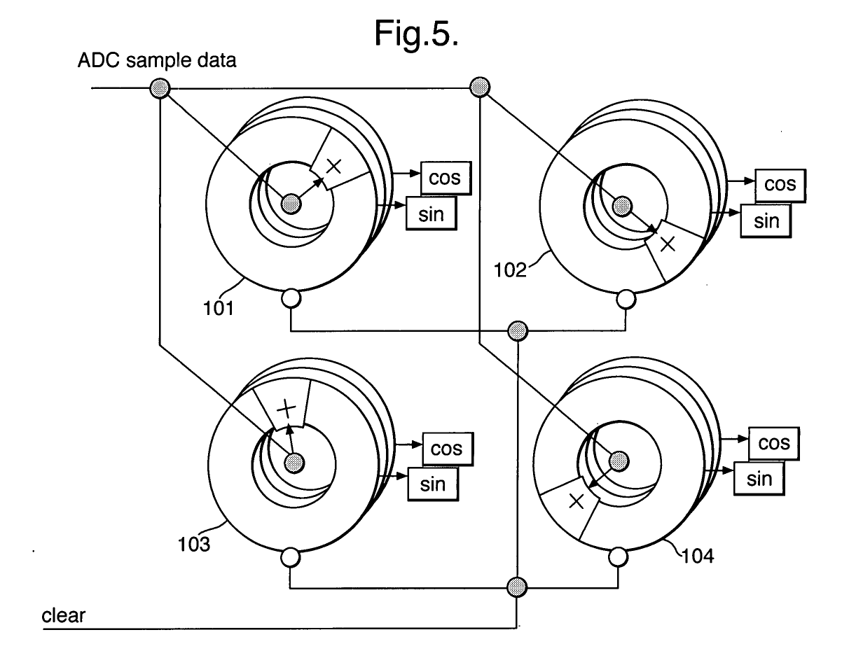

FIG. 5 illustrates schematically how the circular accumulators can be used to eliminate unwanted frequencies and to store values for the current and voltage allowing the calculation of impedance to be updated periodically. The accumulators can be implemented in firmware or in hardware. The following description will describe the complete operation of the detector, ignoring for simplicity the fact that the accumulation and processing phases are performed in different processors.

FIG. 5 shows four blocks 101, 102, 103, 104 corresponding to the four frequencies used. Each of the blocks provides a sine and cosine value for an individual frequency corresponding to the real and imaginary parts of an impedance related parameter. Each block comprises a circular accumulator layer shown as the uppermost layer, and two coefficient layers shown below it all three layers have the same number of elements for any given frequency but the number will vary between the blocks as already described.

Means are provided for clearing all stored values in the accumulator layer by means of a clear signal. The clear signal has the effect of firstly, rendering the sine and cosine values invalid, such that it will yield the value “invalid” if read and secondly setting the selector means to point to an initial cell in the accumulator layer and thirdly zeroing all the accumulators. The initial cell of the accumulator layer is called the first cell and the cell immediately previous to it in the circular sequence of cells is called the last cell. The selector means is shown by an arrow in each of the blocks of FIG. 5.

Each analogue to digitally converted sample from the sensing means is supplied simultaneously to all the blocks, where it is added into the accumulator layer by adding its value to the value of the cell pointed to by the selector. The selector moves clockwise around the cells as value is added. Each block has an integer number of unique positions for the selector, corresponding to the number of cells in the accumulator layer. This number is an integer multiple of the number of samples per cycle of the frequency which the block is detecting. Therefore, the number of cells in each block is different because each block is designed to detect a different frequency.

Each of the lower two layers contains a set of coefficients representing the sine and cosine coefficients for the frequency that is to be detected. These layers are preset based on the choice of frequencies used. The elements marked sine and cosine contain a storage means each able to hold a single result value representing the detected sine or cosine component of the detected frequency, or the value “invalid”. Logic associated with each block updates the stored value whenever the selector points to the last cell in the block and a new value has been added to it.

The updating of the detected result in the form of sine and cosine values is performed by multiplying each coefficient in the corresponding layer by the stored values in the accumulator layer. The result of this operation is then summed to provide a single number that becomes the sine or cosine result value for the block. In the case of the unit using four frequencies there would be four blocks for voltage and four additional blocks for the current. The current and voltage blocks for a single frequency will operate synchronously. This allows the calculation of the impedance to be correct at all times after the first complete cycle despite the fact that the values of the sine and cosine values will accumulate as further cycles are integrated. The process of adding additional cycles together is essential to the noise rejection properties. The fact that the voltage and current blocks operate in synchronism means that in order to get a value for the impedance the accumulated values are simply divided one by the other rather than having to divide each by the number of cycles beforehand.

It is preferred that at least the block corresponding to the highest frequency operates as described above and for a user interface means periodically to use the sine and cosine values for the voltage and current at that frequency in order to calculate and then display the value of one equivalent circuit parameter, in this case the value of R1. In this way the tester will mimic the behaviour of existing impedance testing products such as the BITE (RTM) device manufactured by Megger.

In the case of the Randles equivalent circuit, the calculation of R₂ and C are more sensitive to noise than that for R1. As such, it would be advantageous to leave the calculation of R2 and C until the full sequence has been completed. Consequently, there is only one set of multiplications that need to be performed in order to calculate the final value of the sine and cosine and this would be done at the end of the sequence. Only calculating R2 and C at the end of the operation will also guard against wild fluctuation in their reported values that might result from the random noise in the system.

In the example given above, using the frequencies 55 Hz, 13 Hz, 3 Hz and 2 Hz, and a 2 second 4290 sample sequence, the accumulator layers would have the following minimum number of cells:

Block A=39

Block B=165

Block C=715

Block D=2145

It is of course possible for a block to have an integer multiple of these numbers.

The method and apparatus of the present invention is also applicable to measure the impedance of other circuit components. For example, it is often desirable to be able to accurately measure the currents in a battery system. In order to accurately measure both the DC and AC currents in the battery system without using an external current transformer and without disrupting the battery system requires measuring the magnitude of the ripple current and the float current. Ripple current is caused by the charger and results from the raw rectified mains signal. Float current is the DC current supplied by the charger in order to maintain the state of charge. In addition it is advantageous to measure the frequency content of the system current. Clamp-on and rope current transformers that are typically used to measure battery system currents must be able to contend with both AC and DC currents. Both of these currents can be sizable and lead to the problem of clamp-on current transformers able to cover the range of interest typically not having the required resolution. Using a transformer will also tend to introduce a phase shift in the measured signal and placement with respect to centring around the conductor can have significant effects on the readings. In addition to these technical problems there are also physical and economic problems associated with clamp-on and rope current transformers. They are bulky and heavy and cannot be used where clearances are tight.

An alternative method to measuring the various currents in the battery system is to measure the resistance of an interconnect in the battery system and to use Ohm's law to calculate the current from the voltage drop across the interconnect. Suitable interconnects can be found in the form of inter cell connectors or shunts (straps, bus bars etc). Since most if not all battery systems use straps or bus bars or some other low impedance wiring to interconnect the batteries the method is widely applicable.

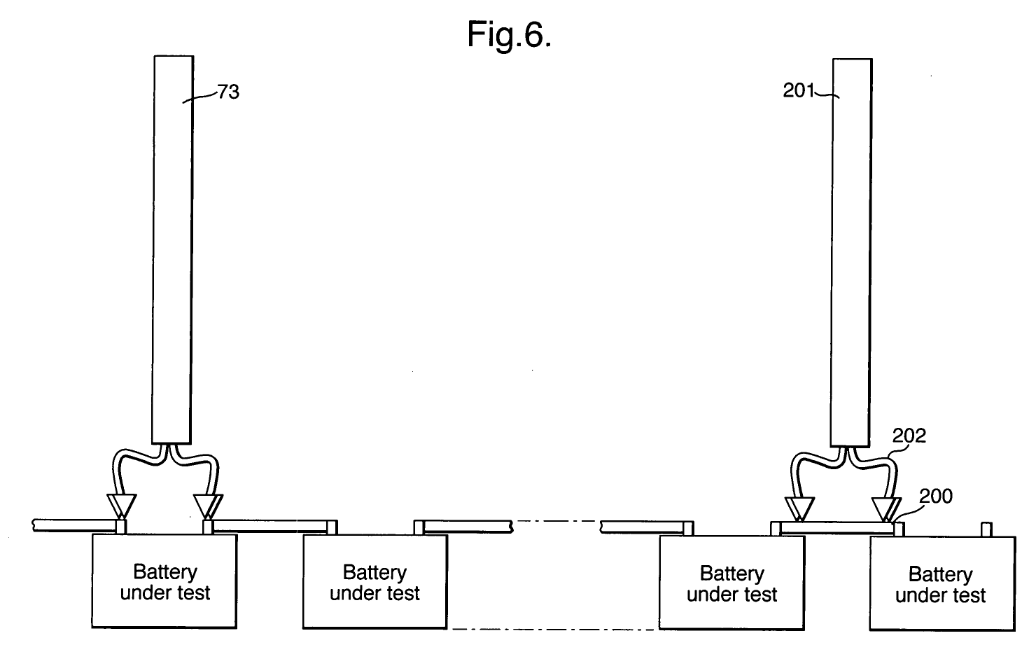

Therefore, measurement of battery system currents can be accomplished through a two step process. These steps can be performed by a single test instrument as described above. FIG. 6 shows a section of a battery system comprising a plurality of cells connected by inter-cell connectors or shunts 200. Also shown is the lead set 201 and probes 202. For comparison the set up for measuring equivalent circuit parameters for a cell, as previously described, using lead set 73, is shown on the left hand side. After the user has connected the tester to a suitable inter-cell connector 200, the test instrument performs the following steps. The signal generating means applies a known test current to the shunt and the voltage drop across the shunt is measured. As the shunt will have a very low resistance accurately measuring the resistance in a noisy electrical environment is difficult. The ripple current of a battery could be as high as 100 Amps, resulting in a much bigger voltage drop across the shunt due to the ripple current than that due to the injected test current (which would typically be a few Amps). In order to overcome this problem the input test signal is constructed of a plurality of discrete frequencies which are carefully chosen to avoid mutual interference, as described above with reference to FIGS. 1-5. By pretesting the battery system current and noise the frequencies can be chosen to be out of band with the battery system currents. The voltage drop across the shunt due to the test current can then be measured by using multiple single frequency homodyne demodulators which very effectively exclude the frequencies where no signal has been output, i.e. the signals due to the ripple current and noise are rejected. The detected voltage is demodulated using the test instrument described with reference to FIG. 4 and the impedance calculated by dividing the detected voltage by the input current. Once the resistance of the shunt is known it can be used to completely measure the battery system currents. This is accomplished by measuring the voltage drop across the shunt without applying any test current and then using Ohm's Law to calculate the current.

1. A method of determining the complex impedance spectrum of a circuit component comprising the steps of:
applying an input signal to the component comprising a fixed duration of a plurality of discrete frequencies simultaneously; and
determining the complex impedance of the component at each of the frequencies using a discrete demodulation technique on two complex impedance related parameters at each of the discrete frequencies;
wherein none of the discrete frequencies is an integer multiple of any other of the discrete frequencies, and
wherein none of the discrete frequencies is a sum of any other two of the discrete frequencies.

2. A method according to claim 1, wherein the demodulation technique is a single frequency homodyne demodulation which is performed at each of the discrete frequencies.

3. A method according to claim 1, wherein the input signal is a current waveform.

4. A method according to claim 1, wherein the plurality of discrete frequencies are applied as a sequence of samples, the sequence containing an integer multiple of cycles of each of the discrete frequencies.

5. A method according to claim 1, wherein processing of the discrete frequencies is performed on a sequence of samples, the sequence containing an integer multiple of cycles of each of the discrete frequencies.

6. A method according to claim 5, wherein the values of the parameters are updated, synchronously with each other for each of the frequencies, at various points in time taking into account all the samples processed up to that point.

7. A method according to claim 1, wherein the duration of the input signal is adjusted so as to comprise a whole number of cycles of an interfering signal.

8. A method according to claim 1, wherein a noise signal is applied across the terminals of the battery simultaneously with the discrete frequencies.

9. A method according to claim 1, further including the step of deriving the values of equivalent circuit parameters from the complex impedance of the component at each of the frequencies.

10. A method according to claim 9, wherein the equivalent circuit parameters are based on the Randles equivalent circuit for a battery and at least four discrete frequencies are used.

11. A method according to claim 10, wherein the derivation of the values of the equivalent circuit parameters includes the step of fitting a curve to a plot of the complex impedance at each of the discrete frequencies or the equivalent thereof, wherein each of the values of the equivalent circuit parameters can be mathematically derived from the curve.

12. A method according to claim 11, wherein an estimate of at least one of the equivalent circuit parameters is updated and displayed at various points in time.

13. A circuit component impedance tester comprising:
signal generation means for applying an input signal, comprising a fixed duration of a plurality of discrete frequencies simultaneously, across the component;
sensing means for detecting two impedance related parameters from the component; and,
processing means for demodulating the measured impedance related parameters at each of the discrete frequencies;
wherein none of the discrete frequencies is an integer multiple of any other of the discrete frequencies, and
wherein none of the discrete frequencies is a sum of any other two of the discrete frequencies.

14. A tester according to claim 13, further comprising a user interface for displaying the equivalent circuit parameters.

15. A tester according to claim 13, wherein the processing means uses a single frequency homodyne demodulation technique performed at each of the discrete frequencies.

16. A tester according to claim 13, wherein the signal generation means generates a current waveform.

17. A tester according to claim 13, wherein the processing means uses the Randles equivalent circuit model and that at least four discrete frequencies are used.

18. A tester according to claim 13, wherein the signal generation means generates the input signal as a sequence of samples.

19. A tester according to claim 13, wherein the processing means analyses the plurality of discrete frequencies as a sequence of samples.

20. A tester according to claim 19, wherein the sequence contains an integer multiple of cycles of each of the discrete frequencies.

21. A tester according to claim 20, wherein the sequence contains an integer number of cycles of an interfering signal.

22. A tester according to claim 21, wherein the signal generation means includes a digital to analogue converter (DAC) for converting the sequence of samples into a waveform.

23. A tester according to claim 22, wherein the processing means includes a plurality of circular accumulators corresponding to each impedance related parameter at each discrete frequency, the length of each accumulator corresponding to the number of samples per cycle at that frequency.

24. A tester according to claim 23, wherein the processing means further comprises means for deriving from the detected impedance related parameters equivalent circuit parameters for the component.

25. A tester according to claim 24, wherein the processing means updates and displays an estimate of at least one of the equivalent circuit parameters at various points in time throughout the test sequence.

26. A method of determining electrical system currents comprising the steps of:
determining the impedance of an electrical interconnect in accordance with claim 1;
measuring the voltage drop across the interconnect as a result of the system currents; and,
determining the electrical system currents from the impedance and voltage using Ohm's law.

27. A method according to claim 26, wherein the discrete frequencies used to determine the impedance of the interconnect are different to those comprising the system currents.

28. A method according to claim 27, wherein the electrical system is a battery system.

29. A tester according to claim 13, further comprising:
means for measuring a voltage drop across an interconnect; and
means for deriving electrical system currents from the impedance related parameters and the voltage drop using Ohm's law.

30. A tester according to claim 29, wherein the discrete frequencies used to determine the impedance of the interconnect are chosen to avoid interference with those comprising the system currents.
